(19) United States
(12) Patent Application Publication
(10) Pub. No.: US 2022/0407290 A1
(43) Pub. Date: Dec. 22, 2022

(54) SEMICONDUCTOR LIGHT EMITTER AND LIGHT OUTPUT APPARATUS

(71) Applicant: FUJIFILM Business Innovation Corp., Tokyo (JP)

(72) Inventors: Junichiro HAYAKAWA, Kanagawa (JP); Akemi MURAKAMI, Kanagawa (JP); Kazuhiro SAKAI, Kanagawa (JP); Tsutomu HAMADA, Kanagawa (JP)

(73) Assignee: FUJIFILM Business Innovation Corp., Tokyo (JP)

(21) Appl. No.: 17/722,384

(22) Filed: Apr. 17, 2022

(30) Foreign Application Priority Data
Jun. 18, 2021 (JP) 2021-102011

(51) Int. Cl. H01S 5/02315; H01S 5/024; H01S 5/042

(52) U.S. Cl. CPC H01S 5/02315; H01S 5/024; H01S 5/042

(57) ABSTRACT

A semiconductor light emitter includes a substrate, a semiconductor multilayer structure including a light emission unit that emits light in an oblique direction with respect to the substrate, a base on which the substrate is disposed, a holding member that holds the substrate at an angle set in advance with respect to the base, a temperature control unit disposed parallel to the substrate to adjust a temperature of the substrate, and a shaping optical system held against the substrate to shape a luminous flux emitted from the semiconductor multilayer structure.

### CROSS-REFERENCE TO RELATED APPLICATIONS

This application is based on and claims priority under 35 USC 119 from Japanese Patent Application No. 2021-102011 filed Jun. 18, 2021.

### BACKGROUND

### (i) Technical Field

The present invention relates to a semiconductor light emitter and a light output apparatus.

### (ii) Related Art

JP2020-136655A discloses a semiconductor multilayer structure, in relation to the semiconductor multilayer structure using a distributed Bragg reflector waveguide, having a light source unit that emits laser light and a light amplification unit that includes an active region formed on a substrate and formed in an extended manner from the light source unit in a direction set in advance along a surface of the substrate, amplifies propagation light propagating in the direction set in advance from the light source unit, and emits the amplified propagating light in an oblique direction with respect to the substrate surface as emission light.

### SUMMARY

In the substrate on which the semiconductor multilayer structure is mounted as described above, the light is emitted in the oblique direction with respect to the substrate. Therefore, in a case where this substrate is mounted on a base of a product housing, the light is emitted in the oblique direction with respect to the base. As a result, there may be a difficulty in usage in design in a case where the semiconductor multilayer structure is mounted on the product.

In addition, in a case where temperature unevenness occurs on the substrate on which the semiconductor multilayer structure is mounted, a frequency and an emission angle of the light emitted from the semiconductor multilayer structure change. Therefore temperature is, for example, desirably adjusted such that the temperature of the substrate becomes uniform.

Aspects of non-limiting embodiments of the present disclosure relate to a semiconductor light emitter capable of adjusting, even with a semiconductor multilayer structure in which light emits obliquely with respect to a substrate, a temperature of the substrate on which the semiconductor multilayer structure is mounted.

Aspects of non-limiting embodiments of the present disclosure relate to a light output apparatus capable of suppressing, even with a semiconductor multilayer structure in which light emits obliquely with respect to a substrate, deterioration of a position display function in a case where the semiconductor multilayer structure is mounted in the light output apparatus capable of emitting position display light for indicating an emission position of the light emitted from the semiconductor multilayer structure.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a semiconductor light emitter including a substrate, a semiconductor multilayer structure including a light emission unit that emits light in an oblique direction with respect to the substrate, a base on which the substrate is disposed, a holding member that holds the substrate at an angle set in advance with respect to the base, a temperature control unit disposed parallel to the substrate to adjust a temperature of the substrate, and a shaping optical system held against the substrate to shape a luminous flux emitted from the semiconductor multilayer structure.

### BRIEF DESCRIPTION OF THE DRAWINGS

Exemplary embodiment(s) of the present invention will be described in detail based on the following figures, wherein:

FIG. 1 is a schematic configuration diagram of a semiconductor light emitter according to a first exemplary embodiment;

FIG. 2 is a plan view of a semiconductor multilayer structure according to the first exemplary embodiment;

FIG. 3 is a cross-sectional view taken along a line A-A′ shown in FIG. 2;

FIG. 4 is a plan view of a printed circuit board according to the first exemplary embodiment;

FIG. 5 is an equivalent circuit diagram of a driver circuit of the semiconductor multilayer structure according to the first exemplary embodiment;

FIGS. 6A and 6B are diagrams showing a state of a current flowing in a return path of the driver circuit;

FIG. 6A is a diagram showing a state where one large thermal via group is formed, and FIG. 6B is a diagram showing a state where a plurality of thermal via groups are formed;

FIGS. 7A and 7B are diagrams showing heat distribution characteristics of the thermal via group;

FIG. 7A is a diagram showing a state where a plurality of thermal vias are disposed in a matrix in the thermal via group, and FIG. 7B is a diagram showing a state where a plurality of thermal vias are disposed in a staggered pattern in the thermal via group;

FIG. 8 is a modification example of the semiconductor light emitter according to the first exemplary embodiment and is a schematic configuration diagram showing an example in which a shape of a holding member is changed;

FIG. 9 is a modification example of the semiconductor light emitter according to the first exemplary embodiment and is a schematic configuration diagram showing an example in which the shape of the holding member is changed to a shape different from the shape of FIG. 8;

FIG. 10 is a modification example of the semiconductor light emitter according to the first exemplary embodiment and is a schematic configuration diagram showing an example in which a disposition position of a temperature control unit is changed;

FIG. 11 is a plan view of another form of the semiconductor multilayer structure according to the first exemplary embodiment;

FIG. 12 is a cross-sectional view taken along a line A-A′ shown in FIG. 11;

FIG. 13 is a plan view of still another form of the semiconductor multilayer structure according to the first exemplary embodiment;

FIG. 14 is a cross-sectional view taken along a line A-A′ shown in FIG. 13;

FIG. 15 is a plan view of still another form of the semiconductor multilayer structure according to the first exemplary embodiment;

FIG. 16 is a cross-sectional view taken along a line A-A′ shown in FIG. 15; and

FIG. 17 is a schematic configuration diagram of a light output apparatus according to a second exemplary embodiment.

### DETAILED DESCRIPTION

Hereinafter, exemplary embodiments of the present disclosure will be described in detail with reference to the drawings.

### First Exemplary Embodiment

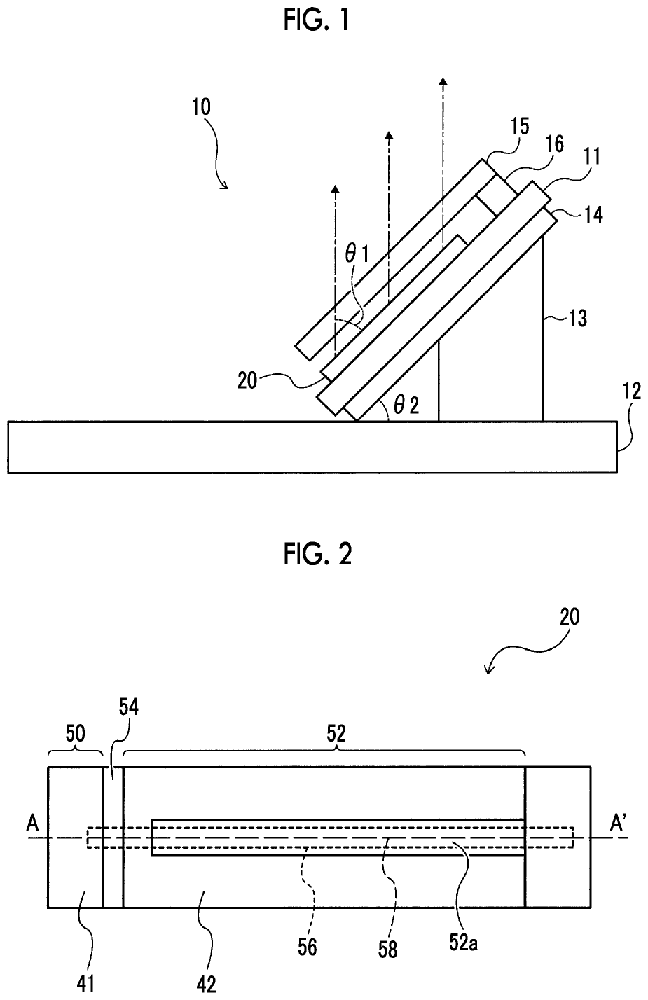

A semiconductor light emitter 10 according to the present exemplary embodiment will be described with reference to FIG. 1. FIG. 1 is a schematic configuration diagram of the semiconductor light emitter 10.

As shown in FIG. 1, the semiconductor light emitter includes a printed circuit board 11, a semiconductor multilayer structure 20 having a light emission unit that emits light in an oblique direction with respect to the printed circuit board 11, a base 12 on which the printed circuit board 11 is disposed, a holding member 13 that holds the printed circuit board 11 at an angle set in advance with respect to the base 12, a temperature control unit 14 disposed in parallel with the printed circuit board 11 to adjust a temperature of the printed circuit board 11, and a shaping optical system 15 held against the printed circuit board 11 to shape a luminous flux emitted from the semiconductor multilayer structure 20.

As the semiconductor multilayer structure 20, any element may be used as long as the element is a semiconductor multilayer structure including the light emission unit that emits the light in the oblique direction with respect to the printed circuit board 11. In the present exemplary embodiment, the semiconductor multilayer structure 20 uses, as an example, a surface-emitting semiconductor multilayer structure using a distributed Bragg reflector (DBR) waveguide.

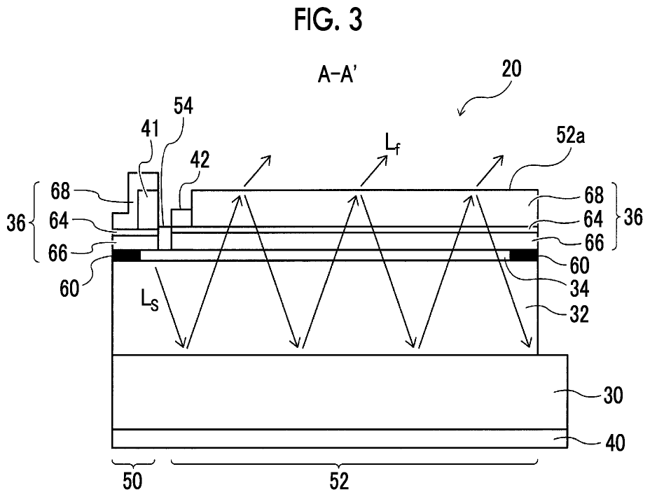

FIG. 2 is a plan view of the semiconductor multilayer structure 20, and FIG. 3 is a cross-sectional view taken along a line A-A′ shown in FIG. 2. As shown in FIG. 2 and FIG. 3, the semiconductor multilayer structure 20 includes a light emitting unit 50 and a light amplification unit 52 that is extended from the light emitting unit 50 and amplifies the light propagating in an extended direction.

The light emitting unit 50 is a portion that generates seed light Ls and is configured as a vertical cavity surface emitting laser (VCSEL) in the present exemplary embodiment. As shown in FIG. 3, the seed light Ls generated from the light emitting unit 50 propagates the light toward the light amplification unit 52.

The light amplification unit 52 has a function of amplifying and emitting the seed light Ls, which is the light generated by the light emitting unit 50. The light amplification unit 52 according to the present exemplary embodiment is a surface-emission light amplification unit using a GaAs-based distributed Bragg reflector waveguide (hereinafter “DBR waveguide”), as an example.

The semiconductor multilayer structure 20 is configured to include a lower DBR 32, an active region 34, a non-conductive region 60, an upper DBR 36, an insulating portion 54, a first P electrode 41, and a second P electrode 42, which are formed on a base layer 30, and an N electrode 40 formed on a back surface of the base layer 30.

In the present exemplary embodiment, the base layer 30 is an n-type GaAs substrate, and the N electrode 40 is provided on the back surface of the base layer 30. On the other hand, the lower DBR 32 according to the present exemplary embodiment is n-type, and the upper DBR 36 is p-type as a whole.

The lower DBR 32 is paired with the upper DBR 36 described below to configure a light source that generates the light in the light emitting unit 50 and to configure a resonator that amplifies and emits the light in the light amplification unit 52.

The lower DBR 32 is a multilayer film reflector configured by alternately and repeatedly stacking two semiconductor layers having a thickness of 0.25A/n each and different refractive indexes in a case where an oscillation wavelength of the semiconductor multilayer structure 20 is A and a refractive index of a medium (semiconductor layer) is n. As a specific example, the lower DBR 32 is configured by alternately and repeatedly stacking an n-type low refractive index layer made of Al_{0.9}Ga_{0.1}As and an n-type high refractive index layer made of Al_{0.2}Ga_{0.8}As.

The active region 34 according to the present exemplary embodiment may be configured to include, for example, a lower spacer layer, a quantum well active region, and an upper spacer layer (not shown). The quantum well active region according to the present exemplary embodiment may be configured of, for example, barrier layers consisting of four layers of Al_{0.3}Ga_{0.7}As and quantum well layers consisting of three layers of GaAs provided between the barrier layers. The lower spacer layer and the upper spacer layer are respectively disposed between the quantum well active region and the lower DBR 32 and between the quantum well active region and the upper DBR 36 to have a function of adjusting a length of the resonator and a function as a clad layer to confine a carrier.

The non-conductive region 60 and a conductive region 58, which are provided on the active region 34, are p-type oxidization constriction layers, that is, current constriction layers. That is, the non-conductive region 60 corresponds to an oxidized region, and the conductive region corresponds to a non-oxidized region. An interface between the conductive region 58 and the non-conductive region 60 forms an oxidation front 56.

In the present exemplary embodiment, one layer of the multilayer film constituting the lower DBR 32 is oxidized to form the non-conductive region 60 (oxidized region), and regions other than the non-conductive region 60 of this one layer are not oxidized to form the conductive region 58 (non-oxidized region). A current flowing from the first P electrode 41 and the second P electrode 42 toward the N electrode 40 is throttled by the conductive region 58.

In the present exemplary embodiment, the non-conductive region 60 (oxidized region) is formed in one layer of the lower DBR 32, but the present invention is not limited thereto. The non-conductive region 60 may be formed in a plurality of layers of the lower DBR 32 or on the upper DBR 36.

The upper DBR 36 is configured to include a p-DBR 66, a phase control layer 64, and an i-DBR 68. Although the p-DBR 66 is p-type, the i-DBR 68 does not contain an impurity. The phase control layer 64 is formed between the p-DBR 66 and the i-DBR 68, and is a layer that adjusts a relationship between the wavelength of the seed light Ls and a vertical resonance wavelength in the light amplification unit 52. In the present exemplary embodiment, the phase control layer 64 is formed by using, for example, a silicon oxide film (SiO₂), a silicon nitride film (SiON), or GaAs.

The insulating portion 54 is a layer that electrically insulates the light emitting unit 50 from the light amplification unit 52 and is formed by ion implantation as an example in the present exemplary embodiment.

The first P electrode 41 is a P electrode of the light emitting unit 50, and the second P electrode 42 is a P electrode of the light amplification unit 52.

In a case where the semiconductor multilayer structure 20 is driven, a positive electrode of a driving power source is applied to the first P electrode 41 and the second P electrode 42 and a negative electrode thereof is applied to the N electrode 40 to cause a drive current to flow from the first P electrode 41 and the second P electrode 42 to the N electrode 40. However, the polarities of the base layer 30, the lower DBR 32, and the upper DBR 36 are not limited thereto. The polarities may be reversed, that is, the base layer 30 may be a p-type GaAs substrate, the lower DBR 32 may be a p-type, and the upper DBR 36 may be an n-type.

The semiconductor multilayer structure 20 according to the present exemplary embodiment will be described in more detail. As shown in FIG. 3, in a case where the current is injected into the active region 34 by the first P electrode 41 and the N electrode 40 provided on both sides of the DBR in the light emitting unit 50, the seed light Ls is generated. The seed light Ls generated in the light emitting unit 50 propagates in a propagation direction from a left side of paper to a right side. In this case, the propagation light propagates mostly in the lower DBR 32, the active region 34, the conductive region 58, and the upper DBR 36 with a predetermined distribution. Therefore, the “DBR waveguide” is configured to include these parts.

The semiconductor multilayer structure 20 using the DBR waveguide is configured of a pair of DBRs provided on the base layer 30, which is a semiconductor substrate, an active region between the pair of DBRs, and a resonator spacer layer. The region sandwiched between the DBRs functions as an optical waveguide, and the light input into the DBR waveguide propagates in a slow light mode while being multiple-reflected in an oblique direction.

In this case, in a case where the current is injected into the active region 34 by the second P electrodes 42 and the N electrodes 40 provided on both sides of the DBR in the light amplification unit 52, light having a wavelength shorter than the vertical resonance wavelength is amplified. The amplified beam is output in a direction that intersects the surface of the base layer 30 and is inclined forward in the propagation direction of the DBR waveguide of the propagation light (obliquely forward direction). In FIG. 3, this output light is indicated as “output light Lf”. That is, a region of the light amplification unit 52 provided with the second P electrode 42 and the N electrode 40 has both functions as the optical waveguide and the light amplification unit.

A light emission region on a surface of the light amplification unit 52 functions as a light emission unit 52a in the present exemplary embodiment.

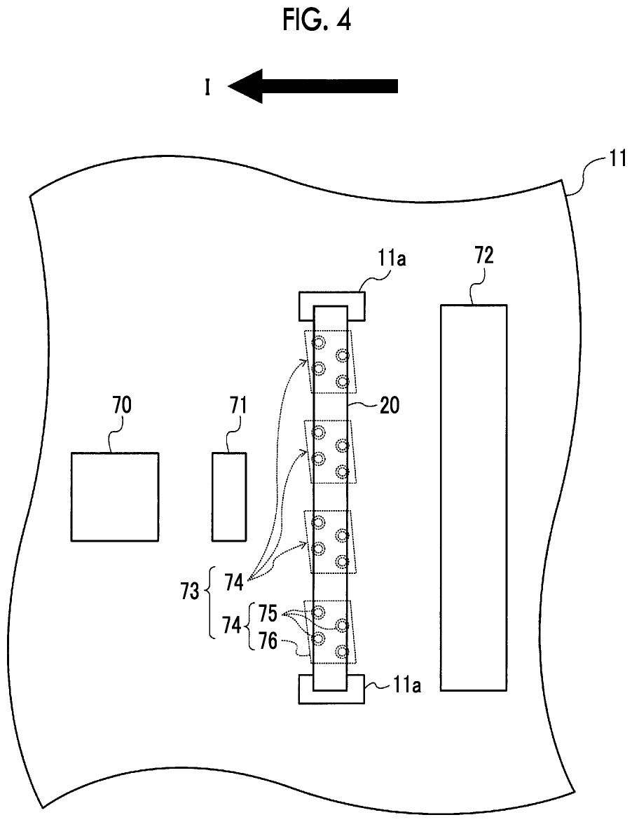

FIG. 4 is a plan view of the printed circuit board 11 on which the semiconductor multilayer structure 20 and the like are mounted. For convenience, in the printed circuit board 11, a surface on which the semiconductor multilayer structure 20 is mounted is referred to as a front surface, and a surface on a back side of the front surface is referred to as a back surface.

The printed circuit board 11 has a multi-layer structure of a front surface layer, an intermediate layer, and a back surface layer. The intermediate layer is a solid ground layer in order to reduce noise in a driver circuit. This intermediate layer (solid ground layer) serves as a return path for the current flowing through the semiconductor multilayer structure 20 mounted on the surface.

As shown in FIG. 4, the semiconductor multilayer structure 20, a driver integrated circuit (IC) 70 that controls the semiconductor multilayer structure 20, a thermistor 71 that measures the temperature of the printed circuit board 11, a capacitor 72 that constitutes a part of the driver circuit of the semiconductor multilayer structure 20, and the like are mounted on the surface of the printed circuit board 11. In the present exemplary embodiment, as an example, a current I is assumed to flow from a right side to a left side in FIG. 4 in the driver circuit.

The semiconductor multilayer structure 20 and the printed circuit board 11 are electrically connected by die bonding via an electrode pad lla formed on the printed circuit board 11. The connection between the semiconductor multilayer structure 20 and the printed circuit board 11 is not limited to the die bonding and may be any connection aspect such as wire bonding.

The thermistor 71 is disposed between the driver IC and the semiconductor multilayer structure 20 on the printed circuit board 11. The thermistor 71 is used for temperature control in the temperature control unit 14 described below.

Further, the printed circuit board 11 is provided with a thermal via portion 73 in a disposition region of the semiconductor multilayer structure 20. The thermal via portion 73 includes a plurality of thermal via groups 74 consisting of a plurality of thermal vias 75, and the plurality of thermal vias 75 in the thermal via group 74 are connected by solid wiring 76 for each thermal via group 74.

The thermal via 75 is a heat dissipation hole penetrating the printed circuit board 11 and is for conducting heat generated by the semiconductor multilayer structure 20 mounted on the front surface of the printed circuit board 11 to the back surface side of the printed circuit board 11.

The solid wiring 76 is a metal layer for radiating the heat conducted from the thermal via 75 on the back surface of the printed circuit board 11.

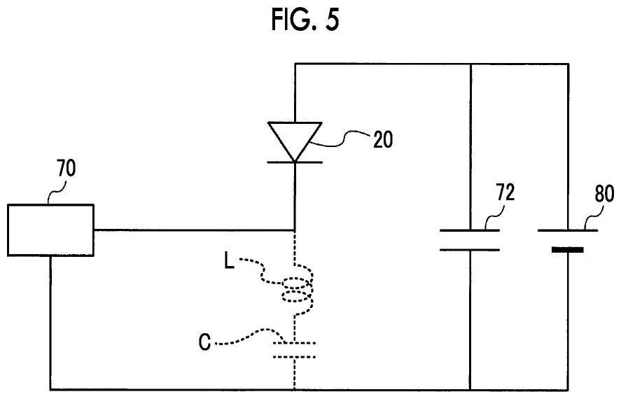

FIG. 5 is an equivalent circuit diagram of the driver circuit of the semiconductor multilayer structure 20. As shown in FIG. 5, in the driver circuit, the semiconductor multilayer structure 20 and the driver IC 70 are connected in series to a power supply 80, and the capacitor 72 is connected in parallel to the semiconductor multilayer structure 20 and the driver IC 70.

A large number of thermal vias 75 penetrating the printed circuit board 11 are, for example, preferably provided to dissipate the heat from the semiconductor multilayer structure 20. However, in a case where too many thermal vias 75 are provided, the return path in the intermediate layer (solid ground layer) is hindered and electromagnetic noise is generated.

Further, since the thermal via 75 becomes a stub, an inductance component (hereinafter referred to as L component) is generated in the driver circuit. Further, since the solid wiring 76 functions as a capacitor by being stacked with the intermediate layer (solid ground layer), a capacitance component (hereinafter referred to as C component) is generated in the driver circuit.

As shown by the dotted line in FIG. 5, these L and C components become parasitic circuits in the driver circuit and vibrate the current flowing through the semiconductor multilayer structure 20. The vibration of the current flowing through the semiconductor multilayer structure 20 increases as both the L component and the C component increase. In a case where the current flowing through the semiconductor multilayer structure 20 vibrates, drive characteristics of the semiconductor multilayer structure 20 deteriorate.

In order to address such a problem, in the present exemplary embodiment, the thermal via portion 73 is formed by being divided into the plurality of thermal via groups 74 in the disposition region of the semiconductor multilayer structure 20.

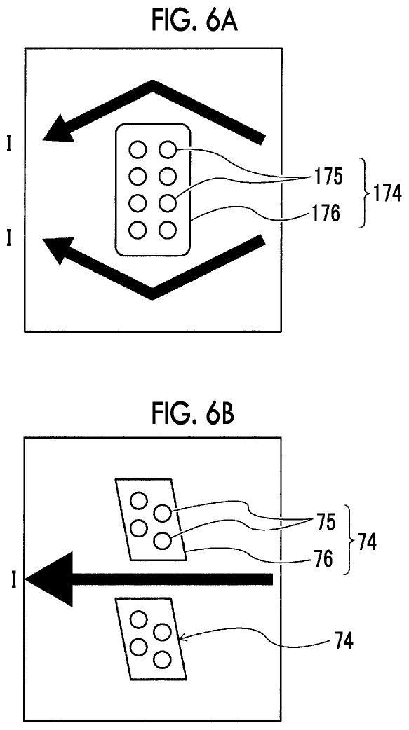

Characteristics of the return path of the driver circuit will be described. FIGS. 6A and 6B are diagrams showing a state of the current flowing in the return path of the driver circuit. FIG. 6A is a diagram showing a state where one large thermal via group 174 is formed, and FIG. 6B is a diagram showing a state where the plurality of thermal via groups 74 are formed.

In a case where one large thermal via group 174 is formed in the disposition region of the semiconductor multilayer structure 20 as in a comparative example shown in FIG. 6A, the current I is required to largely bypass the thermal via group 174 in the return path in the intermediate layer (solid ground layer). Therefore, the flow of the current I is hindered and the electromagnetic noise is generated. Further, an area of solid wiring 176 for the heat dissipation connected to the plurality of thermal vias 175 in the thermal via group 174 is also large. Therefore, the C component in the parasitic circuit is large, and thus the drive characteristics of the semiconductor multilayer structure 20 deteriorate.

On the contrary, in a case where the plurality of thermal via groups 74 are formed in the disposition region of the semiconductor multilayer structure 20 as in the present exemplary embodiment shown in FIG. 6B, the current I can pass through between the plurality of thermal via groups 74. Therefore, a good return path can be secured, and thus the generation of electromagnetic noise can be suppressed. Further, an area of the solid wiring 76 for the heat dissipation connected to the plurality of thermal vias 75 in the thermal via group 74 can be also made smaller in a case where the plurality of thermal via groups 74 are formed than in a case where one large thermal via group 174 is formed. Therefore, the C component in the parasitic circuit becomes small, and thus deterioration of the drive characteristics of the semiconductor multilayer structure 20 can be suppressed.

The return path is easily secured as a spacing between the plurality of thermal via groups 74 is wider, but alternatively, the number of thermal vias 75 formed in the disposition region of the semiconductor multilayer structure 20 is reduced. Consequently, heat dissipation characteristics are reduced. Therefore, the spacing between the plurality of thermal via groups 74 may be designed as appropriate in consideration of the characteristics of the return route and the heat dissipation characteristics.

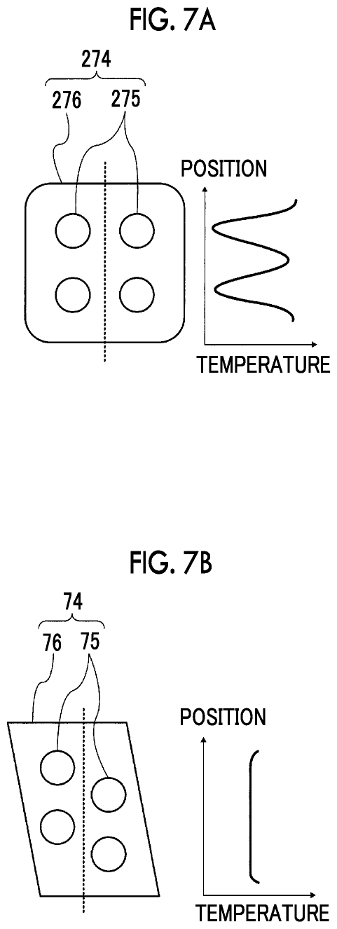

Next, heat distribution characteristics of the thermal via group will be described. FIGS. 7A and 7B are diagrams showing the heat distribution characteristics of the thermal via group. FIG. 7A is a diagram showing a state where a plurality of thermal vias 275 are disposed in a matrix at equal spacings in both a vertical direction and a horizontal direction in the figure in a thermal via group 274, and FIG. 7B is a diagram showing a state where the plurality of thermal vias 75 are disposed in a staggered pattern in the thermal via group 74.

In a case where the plurality of thermal vias 275 are disposed in a matrix at equal spacings in both the vertical direction and the horizontal direction in the thermal via group 274 as in a comparative example shown in FIG. 7A, a temperature of a portion where the thermal via 275 is formed in the thermal via group 274 becomes low, and a temperature of a portion where the thermal via 275 is not formed becomes high. Therefore, temperature unevenness occurs in the thermal via group 274.

On the contrary, as in the present exemplary embodiment shown in FIG. 7B, in a case where the plurality of thermal vias 75 are disposed in a staggered pattern in the thermal via group 74, the disposition of the thermal vias 75 is dispersed. Therefore, the temperature unevenness in the thermal via group 74 can be suppressed. Further, disposition density of the thermal vias 75 in the thermal via group 74 can also be higher in a case where the thermal vias 75 are disposed in a staggered pattern than in a case where the thermal vias 275 are disposed in a matrix. Therefore, the temperature unevenness in the thermal via group 74 is beneficially suppressed.

The temperature control unit 14 is configured of, for example, a temperature control element such as a Peltier element. The temperature control unit 14 is controlled by a control unit (not shown) such that the temperature of the printed circuit board 11 becomes a temperature set in advance based on the temperature of the printed circuit board 11 measured by the thermistor 71.

The temperature control unit 14 is, for example, preferably disposed between the holding member 13 and the printed circuit board 11, or on a printed circuit board 11 side of the holding member 13. In the present exemplary embodiment, as an example, the temperature control unit 14 is disposed on a surface of the printed circuit board 11 opposite to a holding surface of the semiconductor multilayer structure 20 and is disposed between the holding member 13 and the printed circuit board 11.

The shaping optical system 15 is, for example, a cylindrical lens having a positive power in a lateral direction orthogonal to a longitudinal direction in a case where an extension direction of the light amplification unit of the semiconductor multilayer structure 20 is the longitudinal direction. The shaping optical system 15 is held against the printed circuit board 11 via a support column 16.

As shown in FIG. 1, in a case where a light emission angle with respect to the printed circuit board 11 in the semiconductor multilayer structure 20 is 81, and an angle between a holding surface of the printed circuit board 11 and a mounting surface to the base 12 in the holding member 13 is 82, the semiconductor light emitter 10 according to the present exemplary embodiment is configured such that 81+82 is 90°.

In the present exemplary embodiment, the base 12 and the holding member 13 are configured as separate bodies. With such separate bodies, even in a case where 81 changes, a wanted angle, that is, 90° in the present exemplary embodiment can be easily set by changing θ2 accordingly with θ1+θ2.

However, the base 12 and the holding member 13 may be integrally configured.

In the present exemplary embodiment, as an example, the light emission angle θ1 with respect to the printed circuit board 11 in the semiconductor multilayer structure 20 is 45°, and the angle θ2 between the holding surface of the printed circuit board 11 and the mounting surface to the base 12 in the holding member 13 is also 45°.

With such a configuration, even with the semiconductor multilayer structure 20 in which the light is emitted obliquely with respect to the printed circuit board 11, the light is emitted in a direction perpendicular to the base 12. Therefore, in a case where the semiconductor light emitter 10 is mounted on a product, the design becomes easy.

Further, since the temperature control unit 14 is disposed parallel to the printed circuit board 11, the temperature control unit 14 can adjust the temperature uniformly over the entire printed circuit board 11 as compared with a case where the temperature control unit 14 is disposed obliquely to the printed circuit board 11.

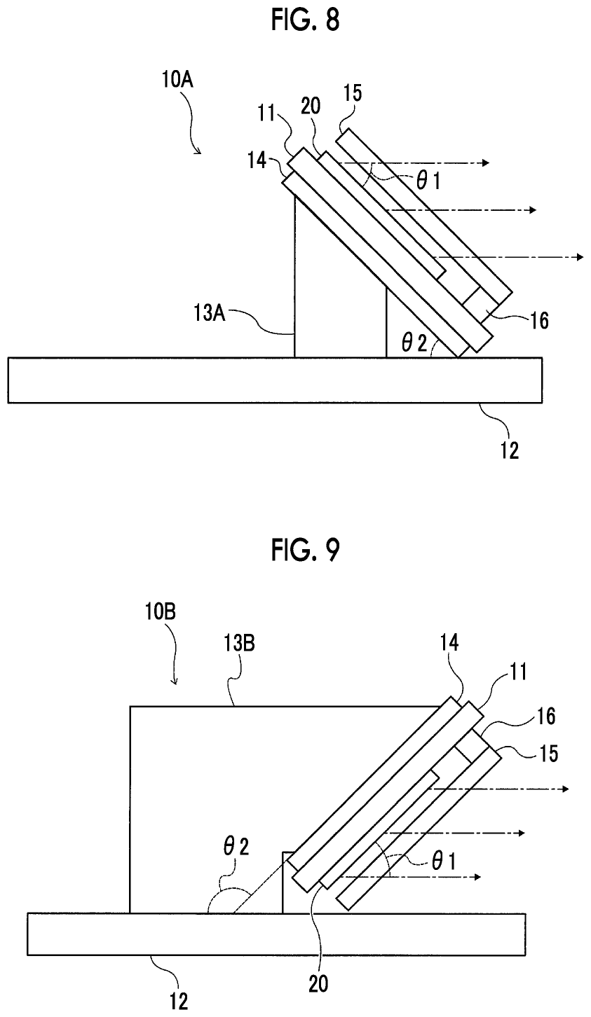

As a modification example of the semiconductor light emitter 10 according to the present exemplary embodiment, a semiconductor light emitter 10A shown in FIG. 8 may be configured such that θ1+θ2 is 0°. In this case, as an example, the light emission angle θ1 with respect to the printed circuit board 11 in the semiconductor multilayer structure 20 is 45°, and the angle θ2 between the holding surface of the printed circuit board 11 and the mounting surface to the base 12 in the holding member 13A is −45°.

Further, a semiconductor light emitter 10B shown in FIG. 9 may be configured such that θ1+θ2 is 180°. In this case, as an example, the light emission angle θ1 with respect to the printed circuit board 11 in the semiconductor multilayer structure 20 is 45°, and the angle θ2 between the holding surface of the printed circuit board 11 and the mounting surface to the base 12 in the holding member 13B is 135°.

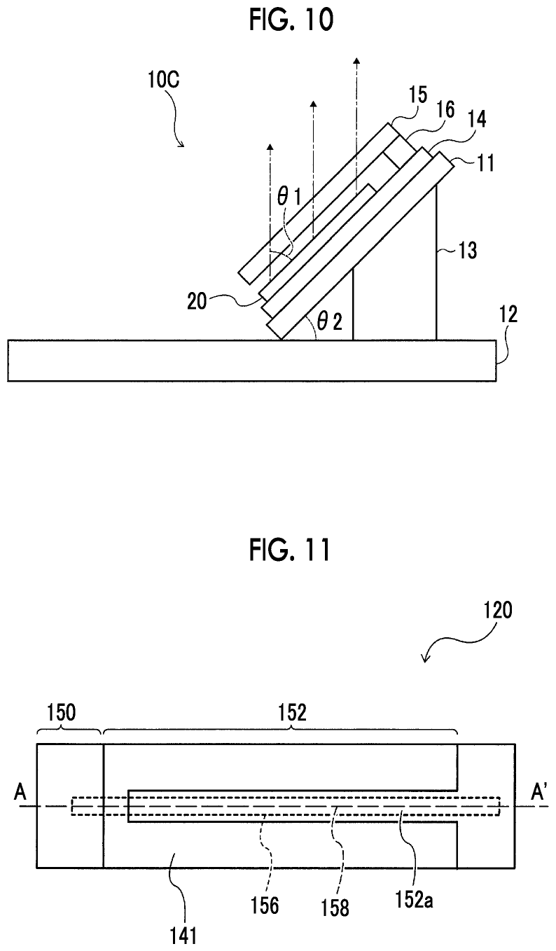

Further, as in a semiconductor light emitter 10C shown in FIG. 10, the temperature control unit 14 may be disposed between the semiconductor multilayer structure 20 and the printed circuit board 11.

In the present exemplary embodiment, the semiconductor multilayer structure 20 emits the light, which is propagated and amplified in the longitudinal direction by the light amplification unit 52, from the light emission unit 52a. However, the light emitted from the light emission unit 52a may not be the amplified light.

In the present exemplary embodiment, the semiconductor multilayer structure 20 amplifies the seed light Ls generated from the light emitting unit 50 by the light amplification unit 52. However, the semiconductor multilayer structure 20 may amplify light emitted by the semiconductor layer itself of the light amplification unit in a state where there is no seed light Ls and a current is directly applied to the light amplification unit.

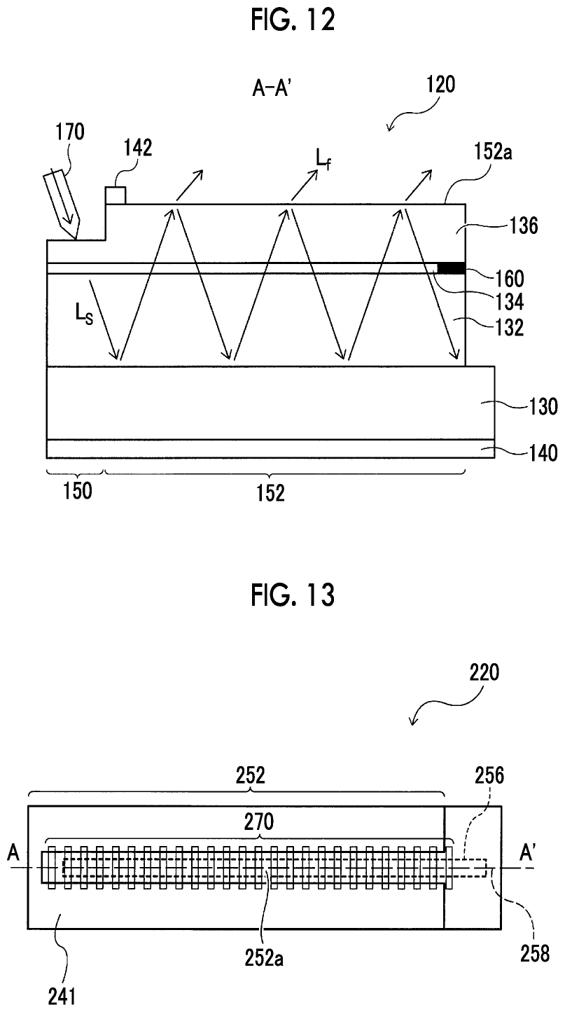

In the present exemplary embodiment, the semiconductor multilayer structure 20 may employ a configuration in which the seed light is introduced from the outside as in a semiconductor multilayer structure 120 shown in FIG. 11 and FIG. 12, instead of the configuration in which the seed light generation unit is integrated on the identical chip as shown in FIG. 3.

FIG. 11 is a plan view of the semiconductor multilayer structure 120, and FIG. 12 is a cross-sectional view taken along a line A-A′ shown in FIG. 11. The semiconductor multilayer structure 120 includes an optical coupling portion 150 and a light amplification unit 152 that is extended from the optical coupling portion 150 and amplifies the light propagating in an extended direction.

The optical coupling portion 150 propagates input light from an external light source (not shown) via an optical fiber 170 and couples an output end of the optical fiber 170 to the optical coupling portion 150 that functions as a light source unit of the semiconductor multilayer structure 120 to introduce the input light into the light amplification unit 52. For example, the vertical cavity surface emitting laser (VCSEL) is used as the external light source. A lensed fiber may be used as the optical fiber 170 from the viewpoint of light coupling efficiency.

The light amplification unit 152 has a function of amplifying and emitting the seed light Ls introduced in the optical coupling portion 150. A light emission region on a surface of the light amplification unit 152 functions as a light emission unit 152a.

The semiconductor multilayer structure 120 is configured to include a lower DBR 132, an active region 134, a non-conductive region 160, an upper DBR 136, and a P electrode 141, which are formed on a base layer 130, and an N electrode 140 formed on a back surface of the base layer 130. Unlike the semiconductor multilayer structure 20 shown in FIG. 3, the upper DBR 136 does not include the phase control layer and the i-DBR.

The non-conductive region 160 and a conductive region 158, which are provided on the active region 134, are p-type oxidization constriction layers, that is, current constriction layers. That is, the non-conductive region 160 corresponds to the oxidized region, and the conductive region 158 corresponds to the non-oxidized region. An interface between the conductive region 158 and the non-conductive region 160 forms an oxidation front 156.

The semiconductor multilayer structure 120 amplifies the light having a wavelength shorter than the vertical resonance wavelength in the same manner as the semiconductor multilayer structure 20. The wavelength and light output of the seed light are variable, which is beneficial for searching for an optimum structure of the amplifier, a seed light condition, and the like. The semiconductor multilayer structure 120 has a simpler structure than the semiconductor multilayer structure 20 and thus can be manufactured by the same process as a general VCSEL process.

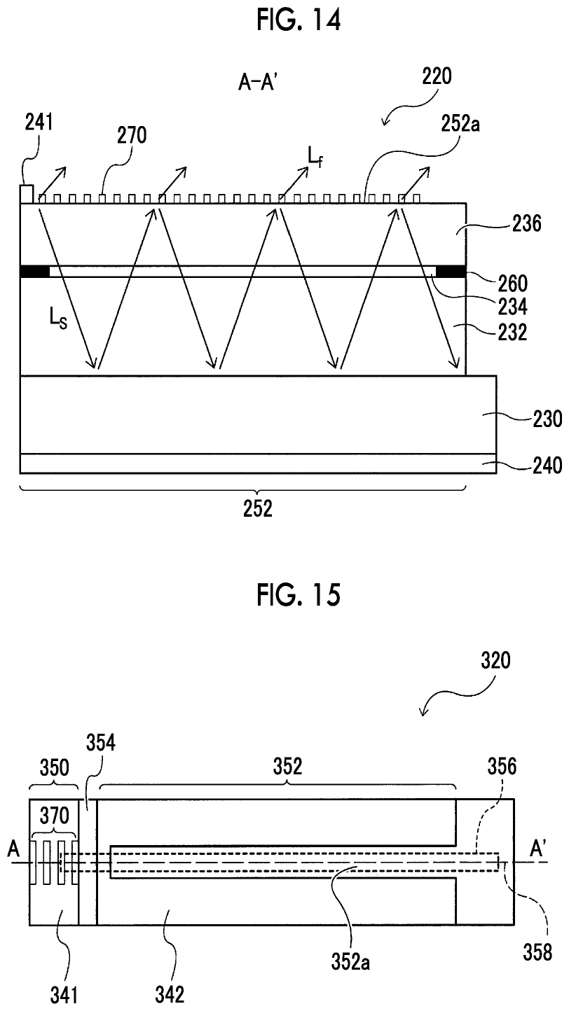

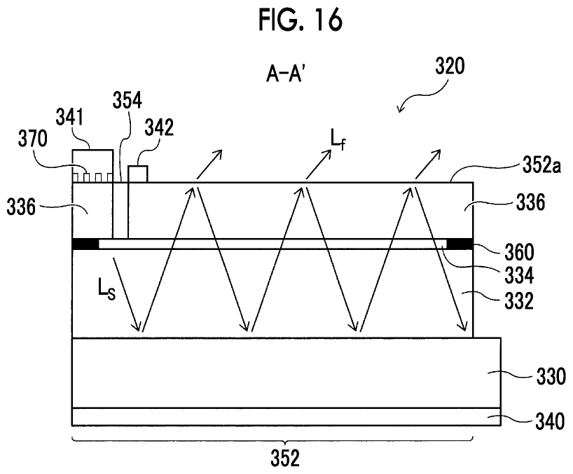

In the present exemplary embodiment, the semiconductor multilayer structure 20 may be employed for a configuration in which a diffraction grating is used as in a semiconductor multilayer structure 220 shown in FIG. 13 and FIG. 14 or a semiconductor multilayer structure 320 shown in FIG. 15 and FIG. 16.

FIG. 13 is a plan view of the semiconductor multilayer structure 220, and FIG. 14 is a cross-sectional view taken along a line A-A′ shown in FIG. 13. The semiconductor multilayer structure 220 includes a light amplification unit 252 that amplifies the light propagating in an extended direction.

The light amplification unit 252 has a function of amplifying and emitting the seed light Ls generated internally in the same manner as the general VCSEL. A light emission region on a surface of the light amplification unit 252 functions as a light emission unit 252a.

The semiconductor multilayer structure 220 is configured to include a lower DBR 232, an active region 234, a non-conductive region 260, an upper DBR 236, a P electrode 241, and a diffraction grating 270, which are formed on a base layer 230, and an N electrode 240 formed on a back surface of the base layer 230.

The non-conductive region 260 and a conductive region 258, which are provided on the active region 234, are p-type oxidization constriction layers, that is, current constriction layers. That is, the non-conductive region 260 corresponds to the oxidized region, and the conductive region 258 corresponds to the non-oxidized region. An interface between the conductive region 258 and the non-conductive region 260 forms an oxidation front 256.

The semiconductor multilayer structure 220 amplifies the light having a wavelength shorter than the vertical resonance wavelength in the same manner as the semiconductor multilayer structure 20. In the semiconductor multilayer structure 220, light in a slow light mode determined by the configuration of the diffraction grating 270 formed in the light emission unit 252a is output. In the semiconductor multilayer structure 220, the seed light is not indispensable, and the light is emitted in the same manner as the general VCSEL, and the wavelength to be amplified is determined by the configuration of the diffraction grating 270.

FIG. 15 is a plan view of the semiconductor multilayer structure 320, and FIG. 16 is a cross-sectional view taken along a line A-A′ shown in FIG. 15. The semiconductor multilayer structure 320 includes a light emitting unit 350 and a light amplification unit 352 that is extended from the light emitting unit 350 and amplifies the light propagating in an extended direction.

The light emitting unit 350 is a portion that generates the seed light Ls and is configured as the VCSEL provided with a diffraction grating 370. As shown in FIG. 16, the seed light Ls generated from the light emitting unit 350 propagates toward the light amplification unit 352.

The light amplification unit 252 has a function of amplifying and emitting the seed light Ls, which is the light generated by the light emitting unit 350. A light emission region on a surface of the light amplification unit 352 functions as a light emission unit 352a.

The semiconductor multilayer structure 320 is configured to include a lower DBR 332, an active region 334, a non-conductive region 360, an upper DBR 336, a first P electrode 341, a second P electrode 342, an ion implantation unit 354, and a diffraction grating 370, which are formed on a base layer 330, and an N electrode 340 formed on a back surface of the base layer 330.

The non-conductive region 360 and a conductive region 358, which are provided on the active region 334, are p-type oxidization constriction layers, that is, current constriction layers. That is, the non-conductive region 360 corresponds to the oxidized region, and the conductive region 358 corresponds to the non-oxidized region. An interface between the conductive region 358 and the non-conductive region 360 forms an oxidation front 356.

The semiconductor multilayer structure 320 amplifies the light having a wavelength shorter than the vertical resonance wavelength in the same manner as the semiconductor multilayer structure 20. In the semiconductor multilayer structure 320, light having a wavelength determined by the configuration of the diffraction grating 370 formed in the light emitting unit 350 is output.

### Second Exemplary Embodiment

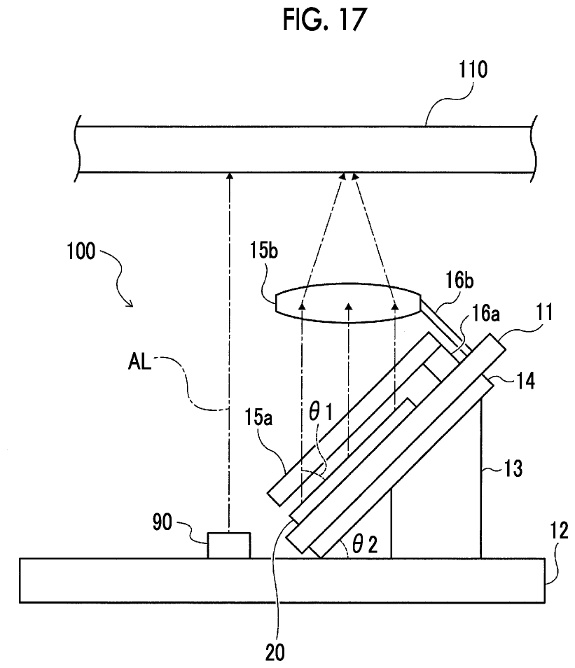

Next, a light output apparatus according to the present exemplary embodiment will be described with reference to FIG. 17. FIG. 17 is a schematic configuration diagram of a light processing apparatus 100 as an example of the light output apparatus. The light processing apparatus 100 is an apparatus that emits processing light to an object to be processed 110 to perform processing treatment on the object to be processed 110. The same reference numbers are assigned to the same components as components of the semiconductor light emitter 10 according to the first exemplary embodiment, and the description of the same components will be omitted.

As shown in FIG. 17, the light processing apparatus 100 includes the printed circuit board 11, the semiconductor multilayer structure 20 that emits the light in an oblique direction with respect to the printed circuit board 11 in a case where the semiconductor multilayer structure 20 is mounted on the printed circuit board 11, the base 12 on which the printed circuit board 11 is disposed, the holding member 13 that holds the printed circuit board 11 at an angle set in advance with respect to the base 12, the temperature control unit 14 disposed in parallel with the printed circuit board 11 to adjust the temperature of the printed circuit board 11, the shaping optical system 15 held against the printed circuit board 11 to shape the luminous flux emitted from the semiconductor multilayer structure 20, and a position display light emission unit 90 held by the base 12 to emit position display light for indicating an emission position of the light emitted from the semiconductor multilayer structure 20.

The shaping optical system 15 includes, as an example, a cylindrical lens 15a having a positive power in a lateral direction orthogonal to a longitudinal direction in a case where an extension direction of the light amplification unit of the semiconductor multilayer structure 20 is the longitudinal direction, and a condenser lens 15b that collects light emitted from the cylindrical lens 15a. The cylindrical lens 15a is held against the printed circuit board 11 via a support column 16a, and the condenser lens 15b is held against the printed circuit board 11 via a support column 16b.

The position display light emission unit 90 indicates the emission position of the processing light (light emitted from the semiconductor multilayer structure 20) to the object to be processed 110 and is configured by, for example, a laser light source.

In a case where a light emission angle with respect to the printed circuit board 11 in the semiconductor multilayer structure 20 is 81, and an angle between a holding surface of the printed circuit board 11 and a mounting surface to the base 12 in the holding member 13 is θ2, the light processing apparatus 100 according to the present exemplary embodiment is configured such that θ1+θ2 is 0° with respect to emission light AL of the position display light emission unit 90.

In the present exemplary embodiment, as an example, the light emission angle θ1 with respect to the printed circuit board 11 in the semiconductor multilayer structure 20 is 45°, and the angle θ2 between the holding surface of the printed circuit board 11 and the mounting surface to the base 12 in the holding member 13 is also 45°. In the position display light emission unit 90, the emission light AL is emitted in the direction perpendicular to the holding surface of the base 12.

With such a configuration, even with the semiconductor multilayer structure 20 in which the light is emitted obliquely with respect to the printed circuit board 11, the processing light can be emitted in parallel with the emission light AL of the position display light emission unit 90. Therefore, display accuracy of the emission position of the processing light can be improved, as compared with a case where the emission light AL and the processing light are not parallel to each other.

Further, the processing light is easily collected at a processing position indicated by the emission light AL in the object to be processed 110, as compared with the case where the emission light AL and the processing light are not parallel to each other. Therefore, the processing portion can be made smaller and processing accuracy can be improved.

In the present exemplary embodiment, the base 12 is configured of one member, and the position display light emission unit 90 and the holding member 13 are further mounted on the same surface of the base 12. With such an aspect, optical axes of the light emitted from the light emission unit of the substrate and the light emitted from the position display light emission unit 90 are set to be more parallel. However, the base 12 may be configured of a plurality of members. In this case, objects having different shapes may be combined, but the base 12 is, for example, preferably configured of a plurality of flat plates. In a case where the base is configured of the plurality of flat plates, for example, two flat plates may be stacked, and the position display light emission unit and the holding member may be mounted on separate flat plates.

Although various typical exemplary embodiments of the present invention have been described above, the present invention is not limited to the various exemplary embodiments and can be appropriately modified without departing from the gist of the present invention.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A semiconductor light emitter comprising:
a substrate;
a semiconductor multilayer structure including a light emission unit that emits light in an oblique direction with respect to the substrate;
a base on which the substrate is disposed;
a holding member that holds the substrate at an angle set in advance with respect to the base;
a temperature control unit disposed parallel to the substrate to adjust a temperature of the substrate; and
a shaping optical system held against the substrate to shape a luminous flux emitted from the semiconductor multilayer structure.

2. A semiconductor light emitter comprising:
a substrate;
a semiconductor multilayer structure including a light emission unit that emits light in an oblique direction with respect to the substrate;
a base on which the substrate is disposed;
a holding member that holds the substrate at an angle set in advance with respect to the base; and
a temperature control unit disposed parallel to the substrate between the holding member and the substrate or on a substrate side of the holding member to adjust a temperature of the substrate.

3. The semiconductor light emitter according to claim 1,
wherein the semiconductor multilayer structure includes a light amplification unit that amplifies the light propagating in an extended direction.

4. The semiconductor light emitter according to claim 2,
wherein the semiconductor multilayer structure includes a light amplification unit that amplifies the light propagating in an extended direction.

5. The semiconductor light emitter according to claim 1,
wherein in a case where a light emission angle with respect to the substrate in the semiconductor multilayer structure is θ1 and an angle between a holding surface of the substrate and a mounting surface to the base in the holding member is θ2, θ1+θ2 is 0°, 90°, or 180°.

6. The semiconductor light emitter according to claim 2,
wherein in a case where a light emission angle with respect to the substrate in the semiconductor multilayer structure is θ1 and an angle between a holding surface of the substrate and a mounting surface to the base in the holding member is θ2, θ1+θ2 is 0°, 90°, or 180°.

7. The semiconductor light emitter according to claim 3,
wherein in a case where a light emission angle with respect to the substrate in the semiconductor multilayer structure is θ1 and an angle between a holding surface of the substrate and a mounting surface to the base in the holding member is θ2, θ1+θ2 is 0°, 90°, or 180°.

8. The semiconductor light emitter according to claim 4,
wherein in a case where a light emission angle with respect to the substrate in the semiconductor multilayer structure is θ1 and an angle between a holding surface of the substrate and a mounting surface to the base in the holding member is θ2, θ1+θ2 is 0°, 90°, or 180°.

9. The semiconductor light emitter according to claim 1,
wherein the semiconductor multilayer structure and the substrate are electrically connected via an electrode pad formed on the substrate.

10. The semiconductor light emitter according to claim 2,
wherein the semiconductor multilayer structure and the substrate are electrically connected via an electrode pad formed on the substrate.

11. The semiconductor light emitter according to claim 3,
wherein the semiconductor multilayer structure and the substrate are electrically connected via an electrode pad formed on the substrate.

12. The semiconductor light emitter according to claim 4,
wherein the semiconductor multilayer structure and the substrate are electrically connected via an electrode pad formed on the substrate.

13. The semiconductor light emitter according to claim 5,
wherein the semiconductor multilayer structure and the substrate are electrically connected via an electrode pad formed on the substrate.

14. The semiconductor light emitter according to claim 1,
wherein the temperature control unit is disposed between the semiconductor multilayer structure and the substrate.

15. The semiconductor light emitter according to claim 1,
wherein the temperature control unit is disposed on a surface of the substrate opposite to a holding surface of the semiconductor multilayer structure.

16. The semiconductor light emitter according to claim 15,
wherein the substrate is provided with a thermal via portion in a disposition region of the semiconductor multilayer structure, and
the thermal via portion includes a plurality of thermal via groups consisting of a plurality of thermal vias, and the plurality of thermal vias in the thermal via group are connected by solid wiring for each thermal via group.

17. The semiconductor light emitter according to claim 16,
wherein a spacing between the thermal via groups adjacent to each other is wider than a spacing between the thermal vias adjacent to each other in the thermal via group.

18. The semiconductor light emitter according to claim 17,
wherein a spacing between the thermal vias adjacent to each other in a longitudinal direction is uniform in the thermal via group.

19. The semiconductor light emitter according to claim 15,
wherein the substrate includes a driver circuit that controls the semiconductor multilayer structure and a temperature measurement unit that measures a temperature of the substrate, and
the temperature measurement unit is disposed between the driver circuit and the semiconductor multilayer structure on the substrate.

20. A light output apparatus comprising:
a substrate;
a semiconductor multilayer structure including a light emission unit that emits light in an oblique direction with respect to the substrate;
a base on which the substrate is disposed;
a holding member that holds the substrate at an angle set in advance with respect to the base; and
a position display light emission unit held by the base to emit position display light for indicating an emission position of the light emitted from the semiconductor multilayer structure,
wherein in a case where a light emission angle with respect to the substrate in the semiconductor multilayer structure is el and
an angle between a holding surface of the substrate and a mounting surface to the base in the holding member is θ2,
θ1+θ2 is 0° with respect to the emission light of the position display light emission unit.
